(19) United States
(12) Patent Application Publication
(10) Pub. No.: US 2026/0362741 A1
(43) Pub. Date: Nov. 12, 2026

(54) SEMICONDUCTOR DEVICE

(71) Applicant: Fast SiC Semiconductor Incorporated, Hsinchu City (TW)

(72) Inventors: Cheng-Tyng YEN, Hsinchu City (TW); Hsiang-Ting HUNG, Hsinchu City (TW); Fu-Jen HSU, Hsinchu City (TW)

(21) Appl. No.: 19/203,618

(22) Filed: May 9, 2025

(51) Int. Cl. H10D 30/66; H10D 62/10; H10D 62/832

(52) U.S. Cl. CPC H10D 30/668; H10D 30/665; H10D 62/102; H10D 62/127; H10D 62/8325

(57) ABSTRACT

This disclosure describes a semiconductor device, including a substrate, a drift layer, and multiple doped regions. A shielding region is provided to enhance electric field dispersion, improving high-voltage performance. The semiconductor device incorporates a doping region to connect the shielding region to the source electrode by a three-dimensional grid-like structure to optimize charge balance and reduce field crowding.

### FIELD OF THE INVENTION

The present disclosure relates to a silicon carbide semiconductor device and more particularly to a silicon carbide semiconductor device low on-resistance and low switching loss.

### BACKGROUND OF THE INVENTION

Silicon carbide (SiC) power devices have emerged as a promising material for power transistors in power conversion applications. Power transistors include metal-oxide-semiconductor field effect transistors (MOSFET), insulated gate bipolar transistors (IGBT), heterostructure field effect transistors (HFET), junction field effect transistors (JFET) and high electron mobility transistors (HEMT). SiC power transistors such as SiC MOSFETs have the advantages of high input impedance, lower driving loss, lower on-resistance, high blocking voltage, lower switching loss, faster switching speed, and larger safe operating area compared to their silicon counterparts.

There are two major types of SiC MOSFET, one is SiC planar MOSFET with a planar gate structure and lateral channel; the other one is SiC trench MOSFET with a trench gate structure and vertical channel.

One of the key considerations of SiC MOSFET is to reduce the on-resistance in a specified area. The total on-resistance of SiC MOSFET includes channel resistance, JFET resistance, contact resistance, drift resistance and substrate resistance. The active region of SiC MOSFET is comprised by an array of unit cells, and one of strategies to reduce the total on-resistance is to increase the channel width density to reduce channel resistance by reducing the cell pitch. Improving the channel resistance is particular important for SiC MOSFET because the channel mobility of SiC MOSFET is much lower than Si MOSFET, and the channel resistance may account for more than 40% of total on-resistance in 650V rated SiC MOSFETs. A simple strategy to reduce on-resistance is reducing the cell pitch to increasing the channel width density. The limitation of further reducing the cell pitch is the minimum dimension of source contact openings for both SiC planar MOSFET and SiC trench MOSFET. The n+regions and p+regions have to connect to the source electrode through the source contact openings. The width of contact opening has to shrink with shrinking cell pitch. A narrow, high aspect ratio source contact opening will be needed for achieving small cell pitch, which poses a challenge on variability, yield and reliability of SiC MOSFETs.

In additional to the on-resistance, another key parameter that impact the performance of SiC MOSFET as a switching components in power electronics systems is the gate-to-drain capacitance (Cgd, also known as Miller capacitance). The performance of power electronics, including a variety of power converters and inverters, is usually measured by the efficiency of power conversion, i.e. how many percentage of input power is converted to output power. The power losses of SiC MOSFETs operated in power electronics come from either conduction loss and switching loss. A lower on-resistance gives a lower conduction loss and a lower Cgd gives a lower switching loss because it allows the SiC MOSFET to turn-on and turn-off at a short period of time.

### SUMMARY OF THE INVENTION

The present disclosure relates to a silicon carbide semiconductor device, comprising: a drift layer, disposed on a SiC substrate, the drift layer having a first conductivity type and a first doping concentration; a first doped region having a second conductivity type, formed in the drift layer; a second doped region having the first conductivity type, formed in the first doped region; a third doped region having the first conductivity type and a second doping concentration, formed in the drift layer, the second doping concentration is higher than the first doping concentration; a gate trench extending from an upper surface of the second doped region through the first doped region and into the drift layer, wherein the gate trench is formed in a manner dividing the drift layer into a plurality of mesas encircled by the gate trench, and wherein each of the mesas comprises an extending portion and a plurality of finger portions extended from the extending portion; a plurality of fourth doped regions having the second conductivity type, formed in the drift layer, wherein each of the fourth doped regions is arranged wholly or partially in the mesas and connected to the first doped region, and wherein each of the fourth doped regions is deeper than the gate trench; a fifth doped region having the second conductivity type, formed in the drift layer and being below or beneath the gate trench, wherein the fifth doped region is connected to the first doped region through the fourth doped regions to maintain at a same electrical potential; a gate electrode arranged in the gate trench and dielectrically insulated from the drift layer by a gate insulator; and a source electrode electrically connected to the second doped region and the fourth doped regions through a plurality of contact openings arranged on the extending portion of the plurality of mesas and is dielectrically insulated from the gate electrode.

The present disclosure furthermore relates to a silicon carbide semiconductor device, comprising: a drift layer, disposed on a SiC substrate, the drift layer having a first conductivity type and a first doping concentration; a plurality of first doped regions having a second conductivity type, formed in the drift layer, wherein each of the first doped regions comprises an extending portion and a plurality of finger portions; a plurality of second doped regions having the first conductivity type, formed in the first doped regions; a third doped region having the first conductivity type and a second doping concentration, formed in the drift layer, the second doping concentration is higher than the first doping concentration, wherein the third doped region has a depth deeper than the first doped regions and forms a JFET region with the first doped regions; a plurality of fourth doped regions having the second conductivity type, formed in the drift layer, wherein each of the fourth doped regions is arranged in the extending portion of the first doped regions and has a depth deeper than the first doped regions; a fifth doped region having the second conductivity type, formed in the drift layer, wherein the fifth doped region is arranged partially or wholly below the JFET region and connected to the first doped regions through the fourth doped regions to maintain at a same electrical potential; a gate electrode provided above the drift layer and dielectrically insulated from the drift layer by a gate insulator; and a source electrode electrically connected to the second doped region and the fourth doped regions through a plurality of contact openings arranged on the extending portion of the plurality of first doped regions and is dielectrically insulated from the gate electrode.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A and FIG. 1B are schematic perspective cross-sectional views of a first embodiment.

FIG. 2 is schematic layout for illustrating the second doped region in the semiconductor device of the first embodiment.

FIG. 3 is schematic layout for illustrating the second doped region and the fourth doped region in the semiconductor device of the first embodiment.

FIG. 4A and FIG. 4B are schematic layouts for illustrating the second doped region and the fourth doped region with the fifth doped region in the semiconductor device of the first embodiment.

FIG. 5A and FIG. 5B illustrate schematic cross-sectional views taken along lines A-A and B-B, respectively, in FIG. 4B. FIG. 6A and

FIG. 6B are schematic perspective cross-sectional views of a second embodiment.

FIG. 7 is schematic layout for illustrating the second doped region in the semiconductor device of the second embodiment.

FIG. 8 is schematic layout for illustrating the second doped region and the fourth doped region in the semiconductor device of the second embodiment.

FIG. 9 is schematic layout for illustrating the second doped region and the fourth doped region with the fifth doped region in the semiconductor device of the second embodiment.

FIG. 10A and FIG. 10B are schematic perspective cross-sectional views of a third embodiment.

FIG. 11 is schematic layout for illustrating the first doped region and the second doped region in the semiconductor device of the third embodiment.

FIG. 12 is schematic layout for illustrating the first doped region and the second doped region and the fourth doped region in the semiconductor device of the third embodiment.

FIG. 13A and FIG. 13B are schematic layout for illustrating the fourth doped region with the fifth doped region in the semiconductor device of the third embodiment.

FIG. 14A and FIG. 14B illustrate schematic cross-sectional views taken along lines A-A and B-B, respectively, in FIG. 13B.

### DETAILED DESCRIPTION OF THE PREFERRED EMBODIMENTS

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

As used herein, the term “and/or” includes any and all combinations of one or more of the associated listed items.

In the drawings, the thickness of layers and regions are exaggerated for clarity. It will also be understood that when an element such as a layer, portion, region, or substrate is referred to as being “on”, “overlie” or “atop” another element, it can be directly on, directly overlie or directly atop the other element or intervening elements may also be present. In contrast, when an element is referred to as being “directly on”, “directly overlie” or “directly atop” another element, there are no intervening elements present.

Relative terms may be used herein to describe a relationship of one element, layer, portion, or region to another element, layer, portion, or region as illustrated in the figures. It will be understood that these terms and those discussed above are intended to encompass different orientations of the device in addition to the orientation depicted in the figures. A number of embodiments will be explained below, identical structural features are identified by identical or similar reference symbols in the figures. As used herein, “lateral” or “lateral direction” should be understood to mean a direction or extent that runs generally parallel to the lateral extent of the semiconductor device. The term “lateral” or “lateral direction” is not limit to a strictly horizontal orientation but may also include directions that are inclined at a certain angle.

The terminology used herein is for the purpose of describing particular embodiments only and is not intended to be limiting of the disclosure. As used herein, the singular forms “a”, “an”, and “the” are intended to include the plural forms as well, unless the context clearly indicates otherwise. It will be further understood that the terms “comprises”, “comprising”, “includes”, and/or “including” when used herein specify the presence of stated features, elements, and/or components, but do not preclude the presence or addition of one or more other features, elements, components, and/or groups thereof. The indefinite articles and the definite articles shall encompass both the plural and singular unless the opposite is clearly apparent from the context.

In this specification, N-doped is referred to as first conductivity type while P-doped is referred to as second conductivity type. Alternatively, the semiconductor devices can be formed with opposite doping relations so that the first conductivity type can be p-doped and the second conductivity type can be n-doped. Furthermore, some figures illustrate relative doping concentrations by indicating “−” or “+” next to the doping type. For example, “N−” means a doping concentration which is less than the doping concentration of an “N”-doping region while an “N+”-doping region has a larger doping concentration than the “N”-doping region. However, indicating the relative doping concentration does not mean that doping regions of the same relative doping concentration have to have the same absolute doping concentration unless otherwise stated. For example, two different N+-doping regions can have different absolute doping concentrations. The same applies, for example, to an N+-doping and a P+-doping region.

While properties, materials, dimensions, shapes, positional interrelationships, conditions for implementation, or the like of respective components have been described in the present disclosure, those are mere examples in all aspects, and each of the embodiments is not limited to those described. Accordingly, numerous modifications which are not illustratively described are conceivable within the scope of each of the embodiments.

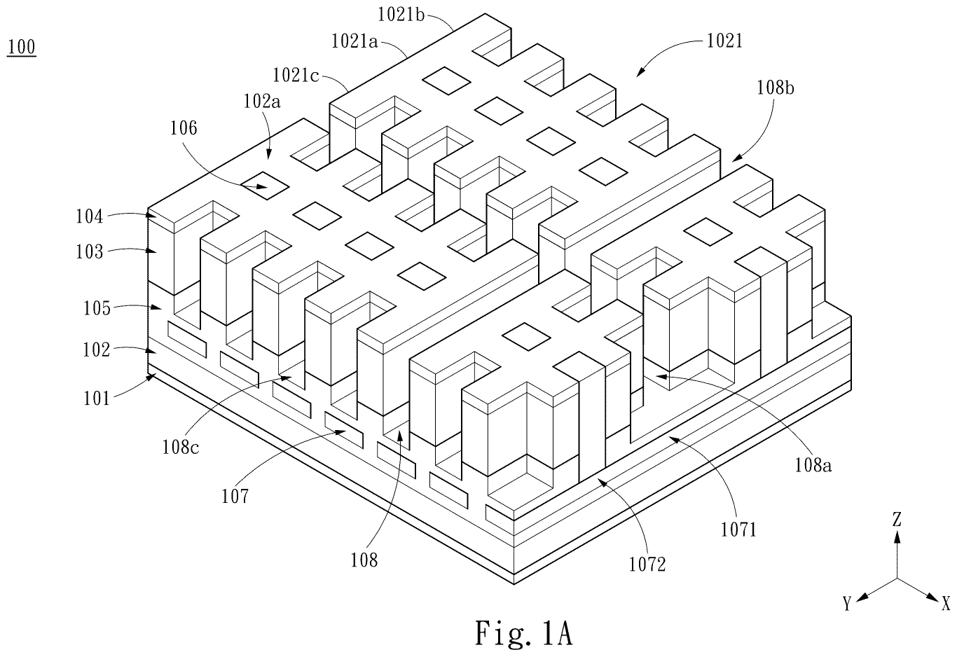

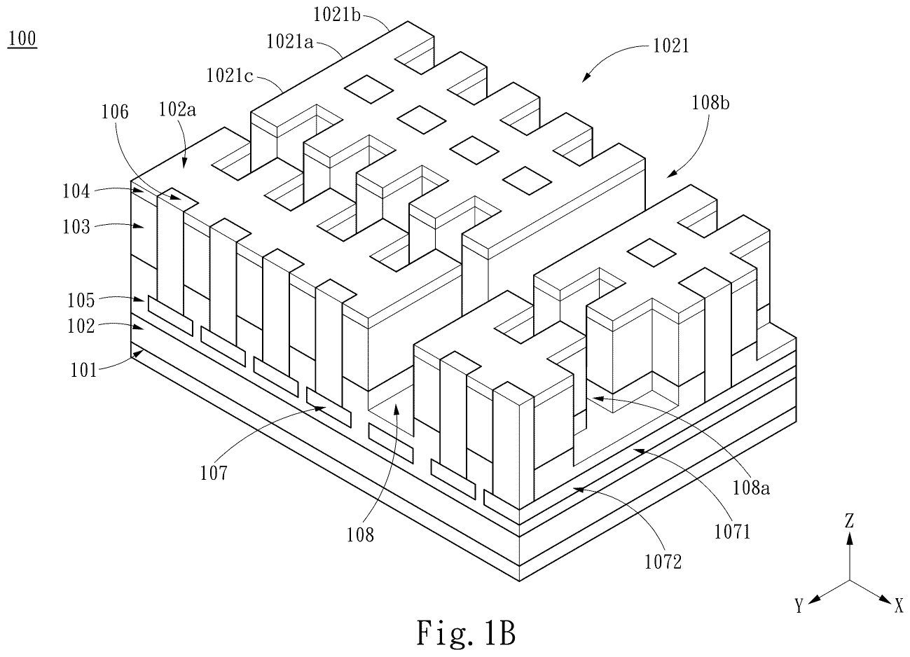

FIG. 1A and FIG. 1B show perspective cross-sectional views of a first embodiment of a semiconductor device 100. The first embodiment is the trench type SiC MOSFET. The semiconductor device 100 comprises a SiC substrate 101, a drift layer 102, a first doped region 103, a second doped region 104, a third doped region 105, a plurality of fourth doped regions 106, a fifth doped region 107 and a gate trenches 108.

The SiC substrate 101 has a first conductivity type (e.g., N-type), for example a nitrogen doped 4H-SiC substrate. The drift layer 102 is disposed on the SiC substrate 101 and has the first conductivity type with a first doping concentration. The first doped region 103 may be disposed on the drift layer 102. The first doped region 103 has a second conductivity type (e.g., P-type), which is opposite to the first conductivity type. The first doped region 103 may be formed by epitaxial processes, for example, by continuously growing a P-type layer directly on a N-type drift layer in a MOCVD reactor or by ion-implantation processes by implanting aluminum ions as dopants into the N-type drift layer to form a counter-doped P-type region. The second doped region 104 is disposed on the first doped region 103 and adjoining a front surface 102a. The second doped region 104 has the first conductivity type. Similar to the first doped region 103, the second doped region 104 may also be formed by epitaxial processes or by ion-implantation processes. The third doped region 105 of the first conductivity type is formed below the first doped region 103 and above the drift layer 102. The third doped region 105 has a second doping concentration higher than the first doping concentration. The third doped region 105 sometimes is referred to as a current spreading region.

In an example, the drift layer 102 is N-type and has a thickness of 10 μm and a doping concentration of 8E15 cm⁻³; the first doped region 103 is P-type and has a thickness of 0.3 μm and a doping concentration of 1E18 cm⁻³; the second doped region 104 is N-type and has a thickness of 0.2μm and a doping concentration of 1E20 cm⁻³.

In the description that follows, for convenience, a direction perpendicular to the front surface 102a, that is, a direction parallel to a normal to the front surface 102a shall be referred to as the normal direction Z of the SiC substrate 101. Also, to view from the normal direction Z shall be referred to as plan view. Further, for convenience, a direction perpendicular to the normal direction Z shall be referred to as a first lateral direction X and a direction perpendicular to both the normal direction Z and the first lateral direction X shall be referred to as a second lateral direction Y. The first lateral direction X is different from the second lateral direction Y. In the following non-limiting examples, the first lateral direction X and the second lateral direction Y are orthogonal to each other.

Gate trenches 108 are introduced from the front surface 102a extending right into the drift layer 102 along a thickness direction. The gate trench 108 has a bottom deeper than a bottom of the first doped region 103. When viewed along a normal to the front surface 102a, the gate trenches 108 may be arranged in gate rows extending along the first lateral direction X and also in gate columns along the second lateral direction Y, wherein the gate trenches 108 alternate sequentially. In detail, the gate trenches 108 may comprise a plurality of first trenches 108a and a plurality of second trenches 108b which may be stripe-shaped and run along the first and second lateral directions, respectively. As shown, the first trenches 108a may be spaced apart from each other in the second lateral direction Y, respectively, and the second trenches 108b may be spaced apart from each other in the first lateral direction X, respectively.

A gate structure is formed in the gate trenches 108. The gate structure comprises a gate insulating layer (not shown) and a gate electrode (not shown). The gate insulating layer is formed on a sidewall and the bottom of the gate trenches 108 and the gate electrode is formed in the gate trenches 108, insulated from the drift layer 102 by the gate insulating layer. The gate insulating layer may be implemented by thermally grown or deposited dielectrics such as SiO₂ or SiOₓN_{y}, and the gate electrode may be implemented by deposition of heavily-doped polysilicon (poly-Si) into the gate trenches 108 followed by etching back or planarization processes.

By forming the gate trenches 108, a plurality of mesas 1021 is provided on the drift layer 102. Each of the mesas 1021 is spaced apart from each other in the first and second lateral directions. In the present embodiment, the gate trenches 108 may further comprise a plurality of bulge trenches 108c, where each of the mesas 1021 comprises an extending portion 1021a and a plurality of finger portions 1021b, 1021c. The extending portion 1021a extends along the first lateral direction X and the finger portions 1021b, 1021c are extended from each of two ends of the extending portion 1021a and along the second lateral direction Y. The finger portions 1021b (or the finger portions 1021c) are spaced by the bulge trenches 108c.

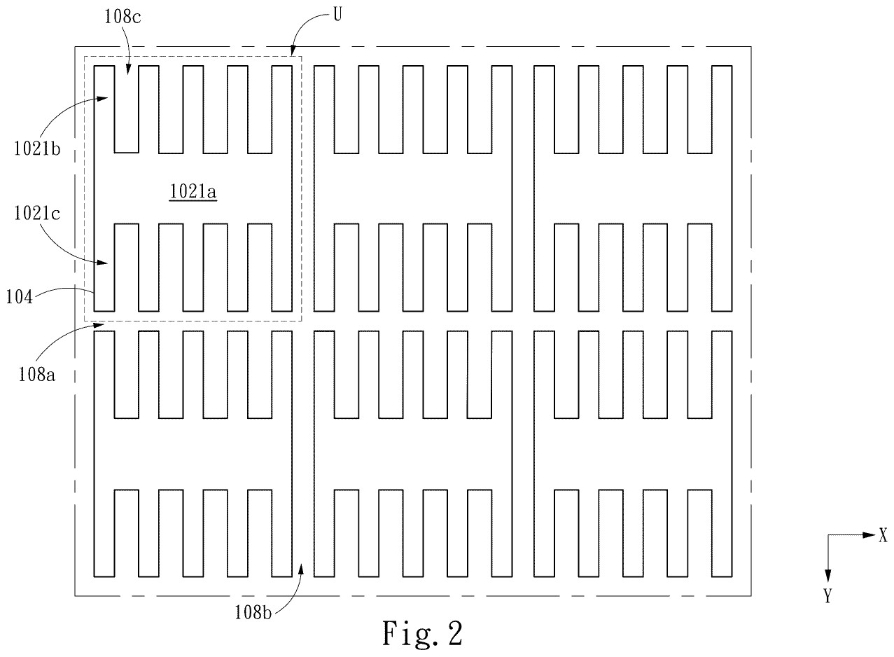

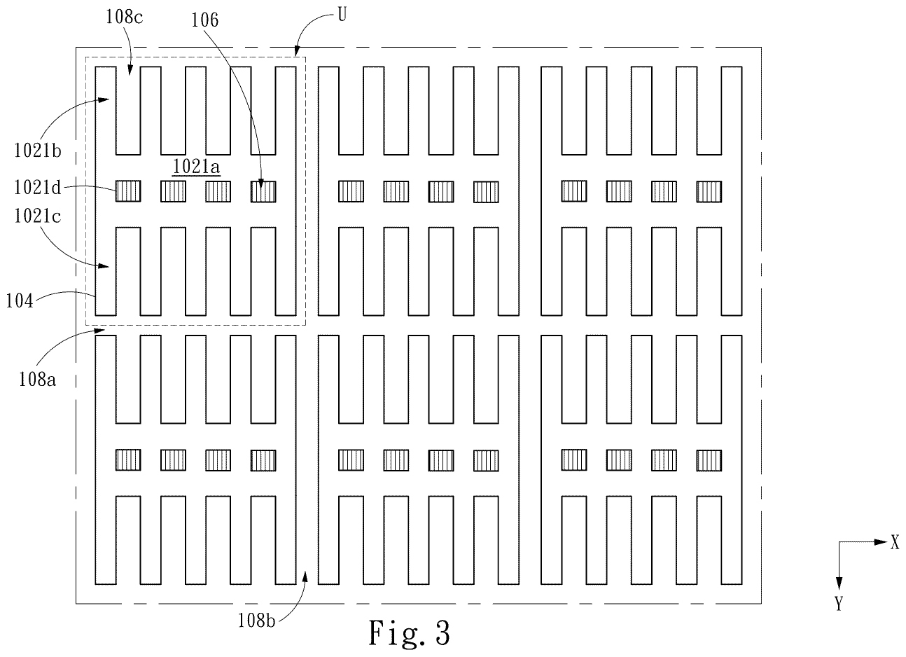

FIG. 2 through FIG. 4B are top views of a portion of the silicon carbide semiconductor device in accordance with the first embodiment of the present disclosure, showing the second doped region 104, the second doped region 104 with the fourth doped region 106 and the second doped region 104 with the fourth doped region 106 and the fifth doped region 107. As shown in FIG. 2, the geometry of the extending portion 1021a is a rectangle. In other embodiments, the extending portion 1021a may be of a square, a circle, an octagon, an oval, or a diamond, or any other regular or irregular shape. From a plan view, the silicon carbide semiconductor device 100 comprises a plurality of multi-layered unit-cells U, where each of the unit-cells U includes a mesa 1021 with one extending portion 1021a and ten finger portions 1021b, 1021c.

In the embodiments described and illustrated herein, the gate trench 108 may be equally spaced, may have equal width, and may form a regular stripe pattern, wherein a center-to-center distance between the gate trenches 108 may be in a range from 0.5 μm to 60 μm. A vertical extension of the gate trench 108 may be in a range from 0.5 μm to 60 μm. At the bottom, the gate trench 108 may have rounded corners to mitigate the field-crowding effect.

The fourth doped regions 106 have the second conductivity type arranged in central areas 1021d within the extending portion 1021a, disposed in the first doped region 103 and adjacent to the second doped region 104. The central area 1021d is located in a region along the extending axes of the bulge trenches 108c. The fourth doped region 106 is for example P-type and has a doping concentration of 1E19 cm⁻³ and a depth of the fourth doped region 106 is deeper than the bottom of the gate trench 108. The fourth doped regions 106 are formed starting from the front surface 102a extending to a depth in the normal direction Z. From a plan view, the fourth doped region 106 may be of a square, a circle, a rectangle, an octagon, an oval, or a diamond, or any other regular or irregular shape.

The fifth doped region 107 has the second conductivity type and is formed in the third doped region 105 and deeper than the gate trench 108 and is electrically connected to the fourth doped regions 106. The fifth doped region 107 is configured as a shielding region that extends along the bottom of the gate trench 108, to reduce the electric field to avoid the rupture of the gate insulating layer when the device is operated at off-state to block a high drain-to-source voltage.

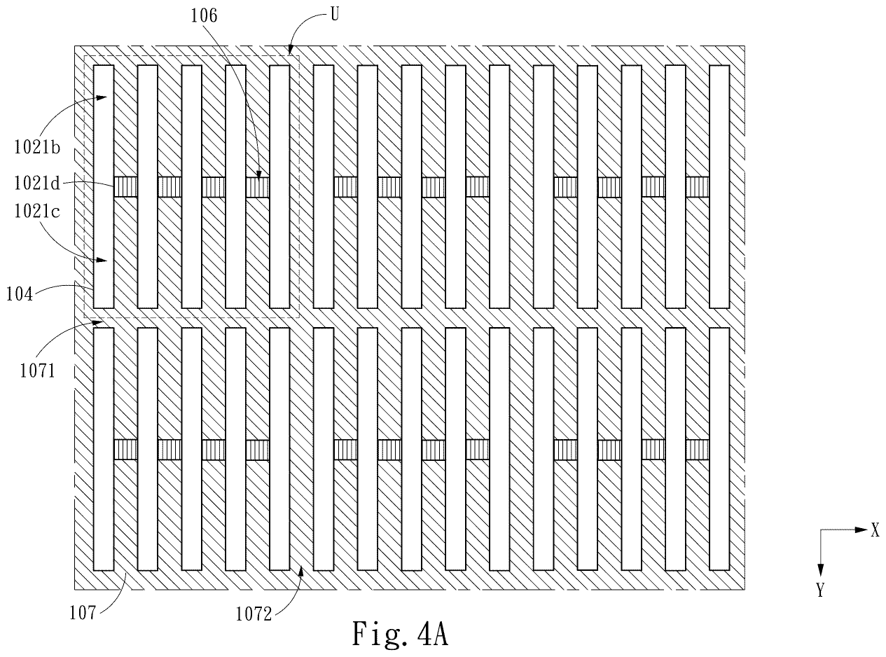

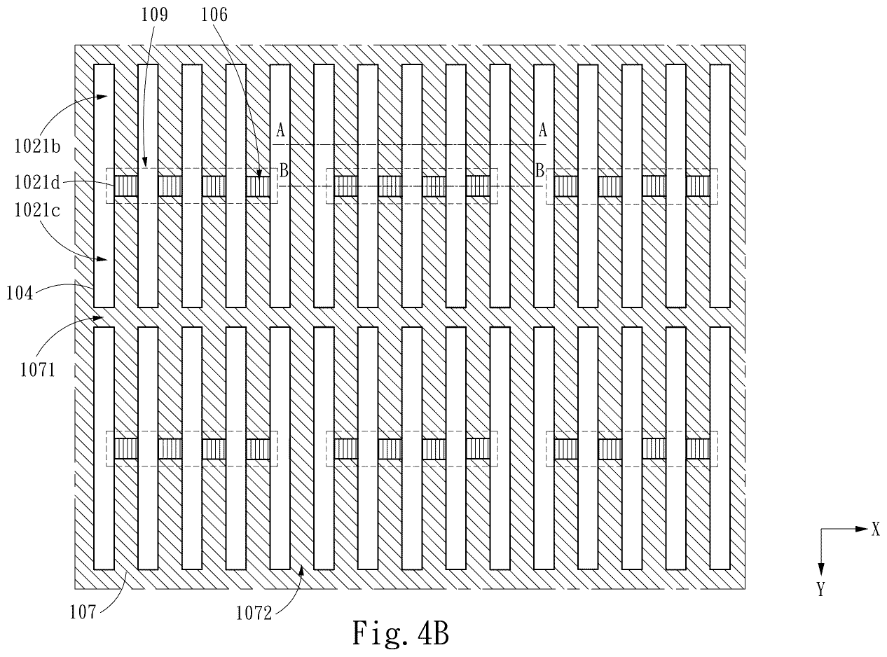

As shown in FIG. 4A, the fifth doped region 107 is formed as a grid structure comprised by a plurality of H-shaped components below the gate trench 108. While in FIG. 4B, the regions where a plurality of source contact openings 109 are located are indicated by dashed lines. The source contact openings 109 may be formed on the extending portion 1021a, allowing the first doped region 103, the second doped region 104, the fourth doped regions 106 and the fifth doped region 107 all electrically connected to a source terminal of MOSFET through a source electrode and maintain a same electric potential. By incorporating the finger portions 1021b, 1021c, the total channel width of the device can be increased to be higher than that of conventional stripe, rectangular, square or hexagonal layouts without violating the minimum design rules of contact openings for any particular platforms. Because the total channel width of each unit-cell U of the device in accordance with the present invention is a perimeter of the mesa 1021.

The fifth doped region 107 may be formed by high energy ion-implantation with energy ranged from 600 keV to 10 MeV, and can be a combination of using N-type and P-type dopants to reduce JFET resistance between the first doped region 103 and the fifth dope region 107. In one example, the depth of the gate trench 108 is 0.6 μm, and the depth of a bottom of the fourth doped region 106 is 0.9 μm and the depth of a top of the fifth doped region is 0.8 μm, and the depth of a bottom of the fifth doped region 107 is 1 μm. In the other example, the depth of a bottom of the fifth doped region 107 is 3 μm, to form a semi super-junction structure with a 5 μm thickness drift layer 102.

The fifth doped region 107 includes a plurality of a first lateral portions 1071 and a second lateral portions 1072, extending along the first lateral direction X and the second lateral direction Y, respectively. In an example, the first lateral portions 1071 and the second lateral portions 1072 have a same width and the first trenches 108a, the second trenches 108b and the bulge trenches 108c have a same trench width. In another example, the first lateral portions 1071 and the second lateral portions 1072 may have a different width and the first trenches 108a, the second trenches 108b and the bulge trenches 108c may also have different trench widths due to process variations or intentional designs.

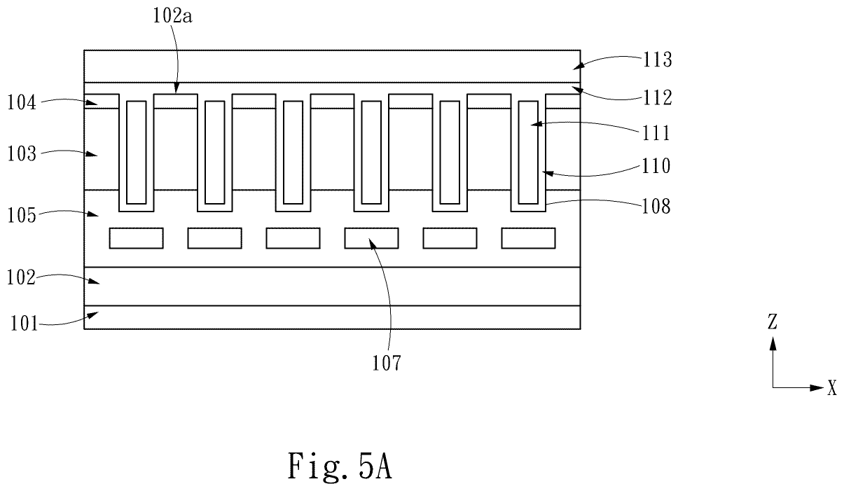

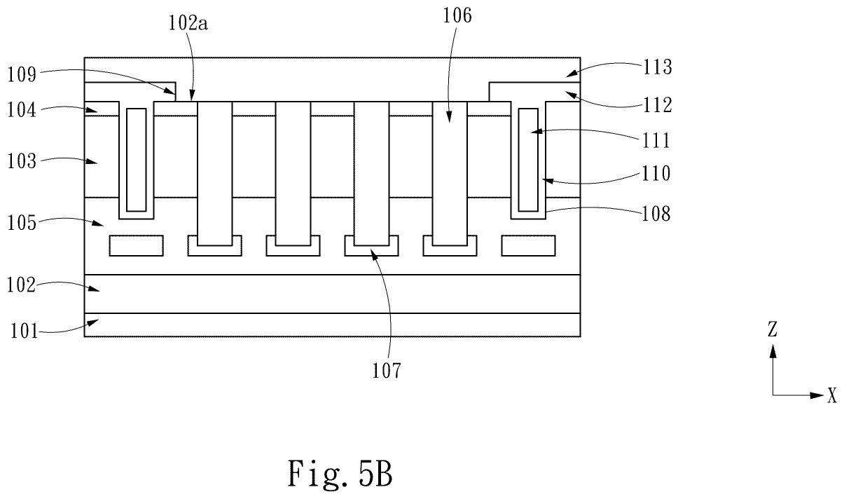

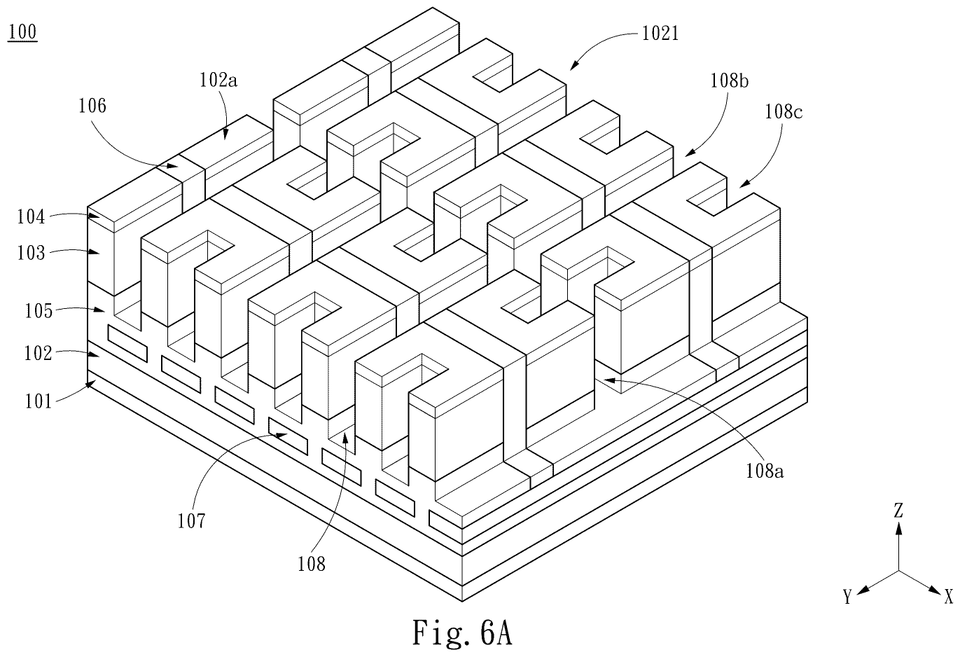

FIG. 5A and FIG. 5B illustrate cross-sectional views taken along lines A-A and B-B in FIG. 4B, respectively. The structures shown in FIG. 5A and FIG. 5B depict an exemplary configuration of the gate and source electrodes in the trench type SiC MOSFET. As seen in FIG. 5A, a gate insulating layer 110 is formed within the gate trench 108, and a gate electrode 111 is formed on the gate insulating layer 110. Subsequently, an interlayer dielectric (ILD) layer 112 is formed above the front surface 102a. Referring next to FIG. 4B and FIG. 5B, portions of the ILD layer 112 are removed to form the source contact openings 109 passing through the ILD layer 112. The source contact openings 109 expose the fourth doped regions 106 and a portion of the second doped regions 104. A source electrode 113 is formed over the ILD layer 112 and filled into the source contact openings 109 to electrically contact the fourth doped regions 106 exposed therein. Accordingly, the fifth doped region 107 is electrically connected to the source electrode 113 via the fourth doped regions 106. The ILD layer 112 electrically isolates the source electrode 113 from the gate electrode 111.

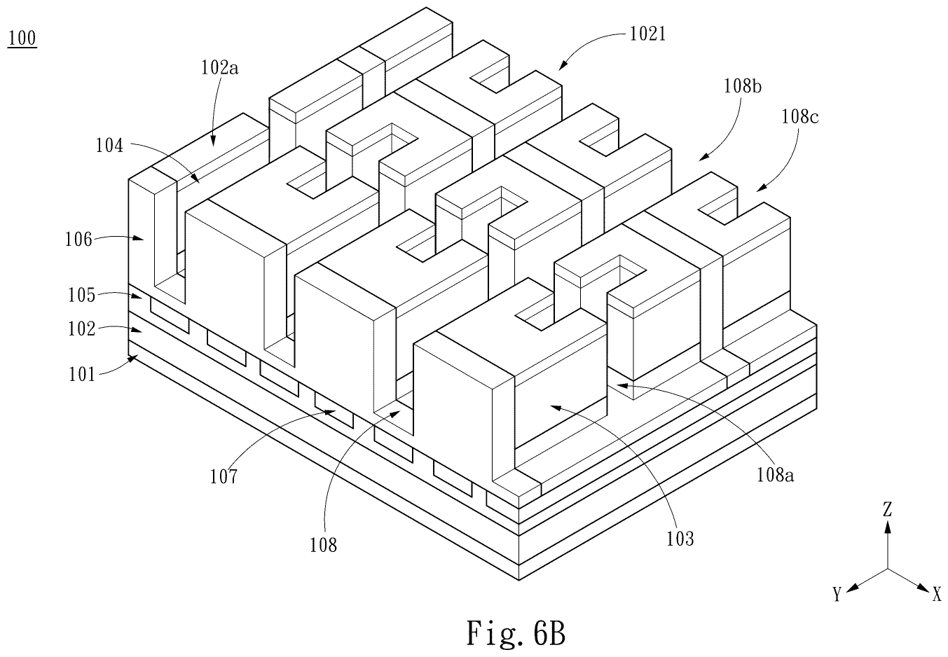

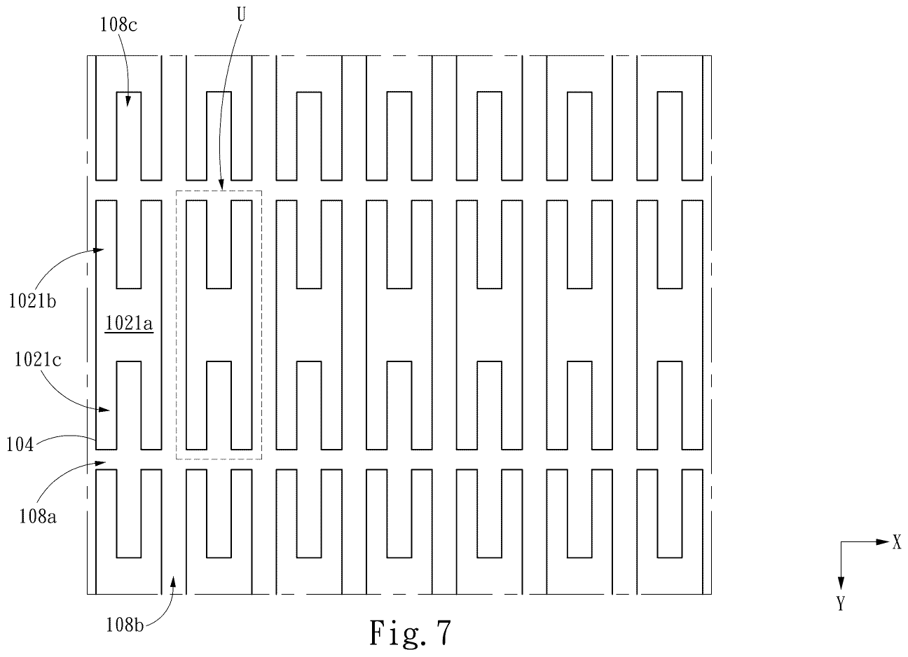

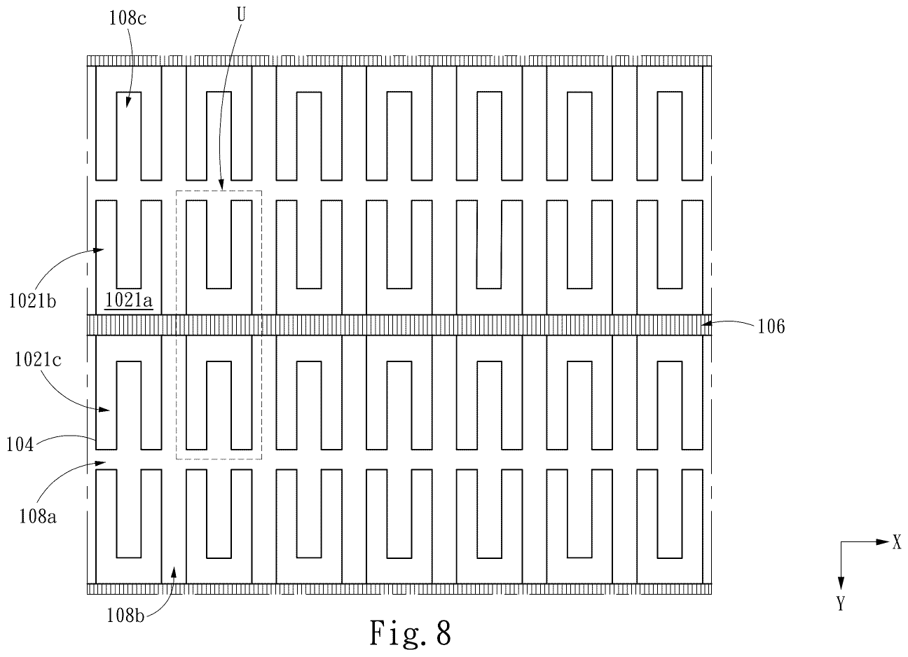

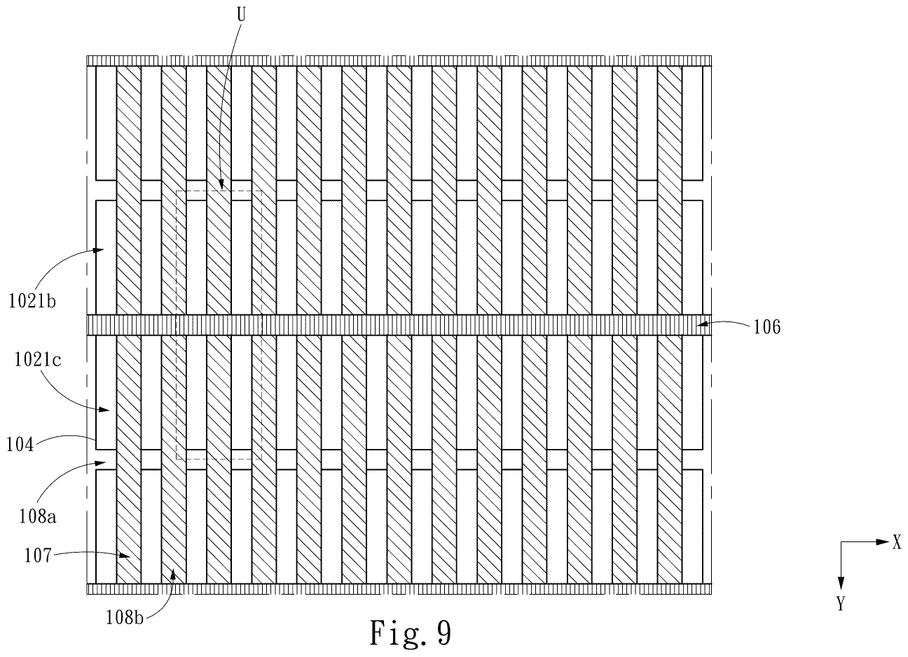

FIGS. 6A to 6B illustrate a silicon carbide semiconductor device in accordance with a second embodiment of the present disclosure. The configurations of the gate trenches 108, the first doped region 103, the second doped region 104, the third doped region 105 and the fifth doped region 107 are similar to the first embodiment. In comparison to the first embodiment, each of the multi-layered unit-cells U comprises a mesa 1021 with one extending portion 1021a and four finger portions 1021b, 1021c as shown in FIG. 7 and FIG. 8, where in FIG. 7 the fourth doped regions 106 are omitted. In this embodiment, the fourth doped regions 106 extend continuously along the first lateral direction X without interruption as shown in FIG. 6A, FIG. 8 and FIG. 9. The fourth doped regions 106 are deep enough to electrically connect to the fifth doped region 107 and ensure the electric potential of the first doped region 103, the second doped region 104, the fourth doped regions 106 and the fifth doped region 107 can be maintained the same with the source electrode by forming an electric Ohmic contacts with a portion of the second doped region 104 and the fourth doped regions 106 through the contact openings (not shown) landed on the extending portion 1021a of the mesa 1021.

In some examples, the silicon carbide semiconductor device 100 further comprises an edge termination structure, the edge termination structure comprises a plurality of floating guard rings (FGRs), a single-zone or multi-zones junction termination extensions (JTEs) or a combination of FGRs and JTEs. The FGRs and JTEs are formed by the first doped region 103, the fourth doped regions 106 and the fifth doped region 107.

In one example, the fifth doped region 107 may extend much deeper than another to form a semi super-junction or super-junction structures with the drift layer 102 and the third doped region 105, having a charge imbalance between −20% and +20%.

The aforementioned embodiments are SiC MOSFETs with trench gate. The fifth doped region 107 formed below the trench gate can also be used in SiC MOSFETs with planar gate.

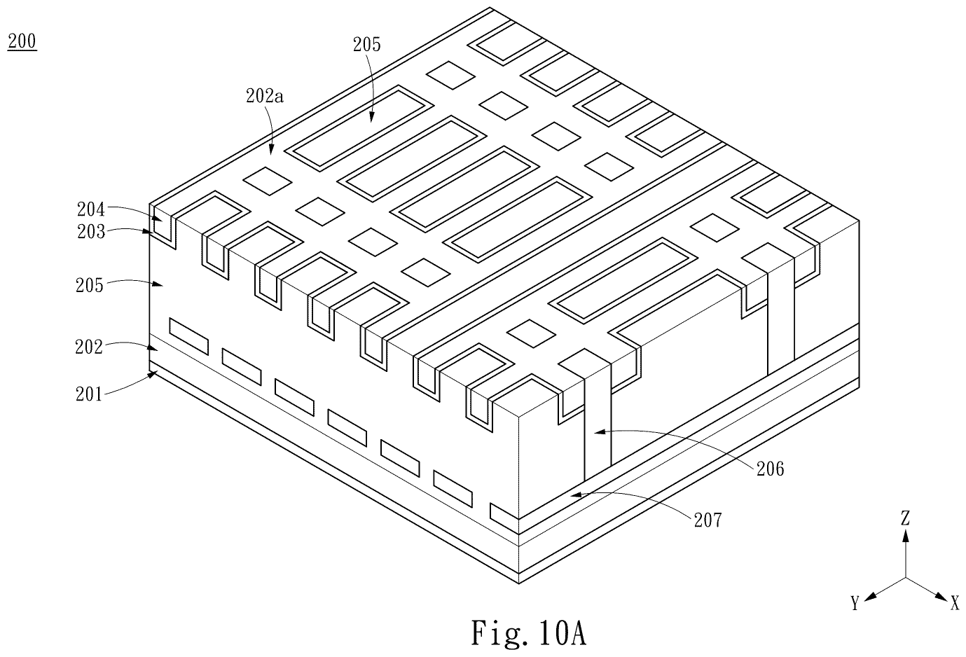

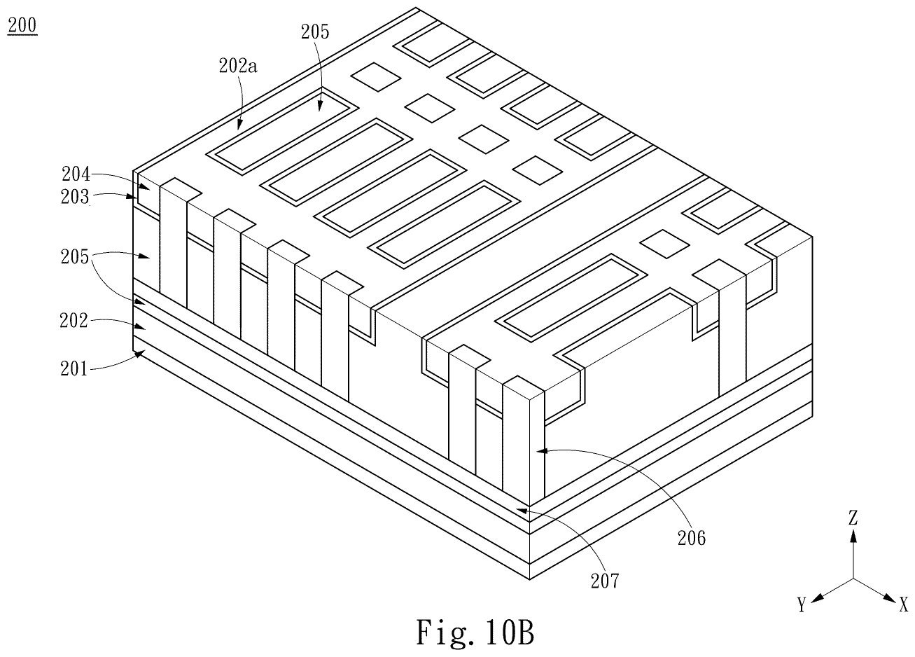

FIG. 10A and FIG. 10B show perspective cross-sectional views of a third embodiment of a semiconductor device 200. The third embodiment is a planar SiC MOSFET. The semiconductor device 200 comprises a SiC substrate 201, a drift layer 202, a plurality of first doped regions 203, a plurality of second doped regions 204, a third doped region 205, a plurality of fourth doped regions 206 and a fifth doped region 207.

The drift layer 202 is disposed on the SiC substrate 201 and has the first conductivity type. The first doped regions 203 may be disposed in the drift layer 202 and adjoining to a front surface 202a. The first doped regions 203 have a second conductivity type (e.g., P-type), which is opposite to the first conductivity type. The first doped regions 203 may be formed by implanting aluminum ions as dopants into the N-type drift layer 202 to form a counter-doped P-type region adjoining to the front surface 202a. The first doped regions 203 form a plurality of first P-N junctions and a plurality of JFET regions with the drift layer 202. The drift layer 202 has a first doping concentration of the first conductivity type.

The second doped regions 204 may be disposed in the first doped regions 203. The second doped regions 204 are laterally adjacent to the first doped regions 203. The second doped regions 204 form a plurality of second P-N junctions with the first doped regions 203. A plurality of channel regions are provided between the first P-N junctions and the second P-N junctions along the front surface 202a. The second doped regions 204 are formed by implanting nitrogen ions or phosphorus ions as dopants into the P-type first doped regions 203 to form a heavily doped N-type regions. That is, the second doped regions 204 are disposed in the first doped regions 203.

The third doped region 205 of the first conductivity type is formed below the first doped region 203 and above the drift layer 202. The third doped region 205 has a second doping concentration higher than the first doping concentration. The third doped region 205 has a depth deeper than the first doped regions 203 and forms a JFET region with the first doped regions 203.

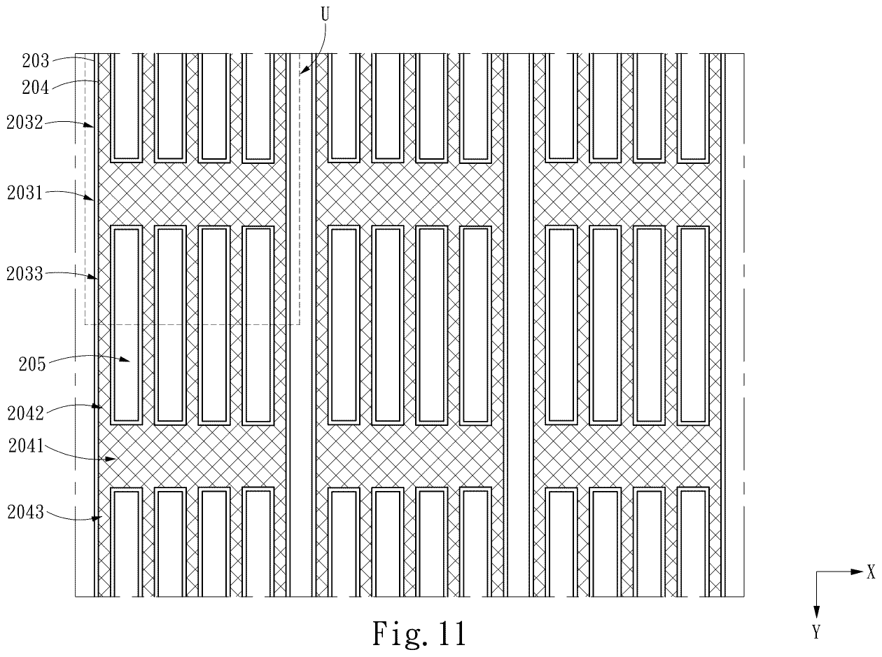

FIG. 11 through FIG. 13B are top views of a portion of the silicon carbide semiconductor device in accordance with the third embodiment of the present disclosure, showing only the first doped regions 203 together with the second doped region 204, the fourth doped region 206 and the fifth doped region 207, and the first doped regions 203 together with the second doped region 204 and the fourth doped region 206.

From a plan view, the first doped regions 203 include a plurality of first extending portions 2031 and a plurality of first finger portions 2032, 2033. The first extending portions 2031 extend along the first lateral direction X and the first finger portions 2032, 2033 are extended from each of two ends of the first extending portion 2031 and along the second lateral direction Y. The second doped regions 204 include a plurality of second extending portions 2041 and a plurality of second finger portions 2042, 2043. The second extending portions 2041 extend along the first lateral direction X and the second finger portions 2042, 2043 are extended from each of two ends of the second extending portion 2041 and along the second lateral direction Y. As shown in FIG. 11 to FIG. 13B, the semiconductor device 200 are comprised by a plurality of unit-cells U in a plan view. Each of the unit-cells U includes one first extending portion 2031, one second extending portion 2041, ten first finger portions 2032 and 2033, ten second finger portions 2042 and 2043 and four fourth doped regions 206.

The fourth doped regions 206 have the second conductivity type formed in the first extending portions 2031 and arranged along the extension axes of the JFET regions and adjacent to the second doped regions 204. The fourth doped region 206 is for example P-type and has a doping concentration of 1E19 cm⁻³. The fourth doped regions 206 are formed starting from the front surface 202a extending to a depth deeper than the first doped regions 203 in the normal direction Z. From the plan view, the fourth doped region 206 may be of a square, a circle, a rectangle, an octagon, an oval, or a diamond, or any other regular or irregular shape.

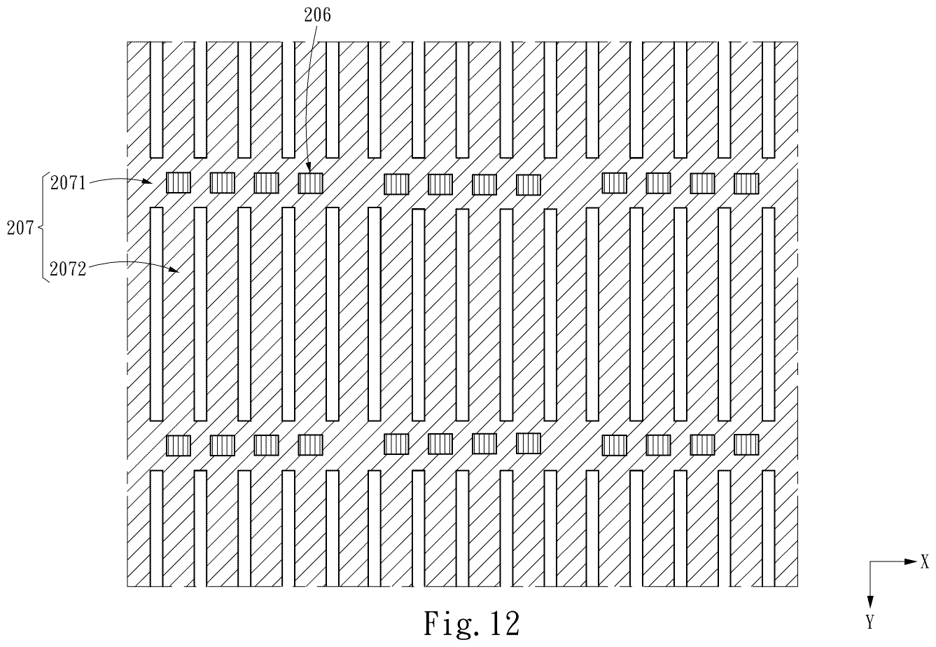

The fifth doped region 207 has the second conductivity type and is formed in the drift layer 202 and deeper than the first doped regions 203. The fifth doped region 207 is arranged partially or wholly below the JFET region and electrically connected to the fourth doped regions 206. The fifth doped region 207 is configured to shield the electric field posed on gate insulator formed above the JFET regions. As shown in FIG. 12, the fifth doped region 207 is formed as a grid structure with a plurality of a first lateral portions 2071 and a second lateral portions 2072 extending along the first lateral direction X and the second lateral direction Y, respectively.

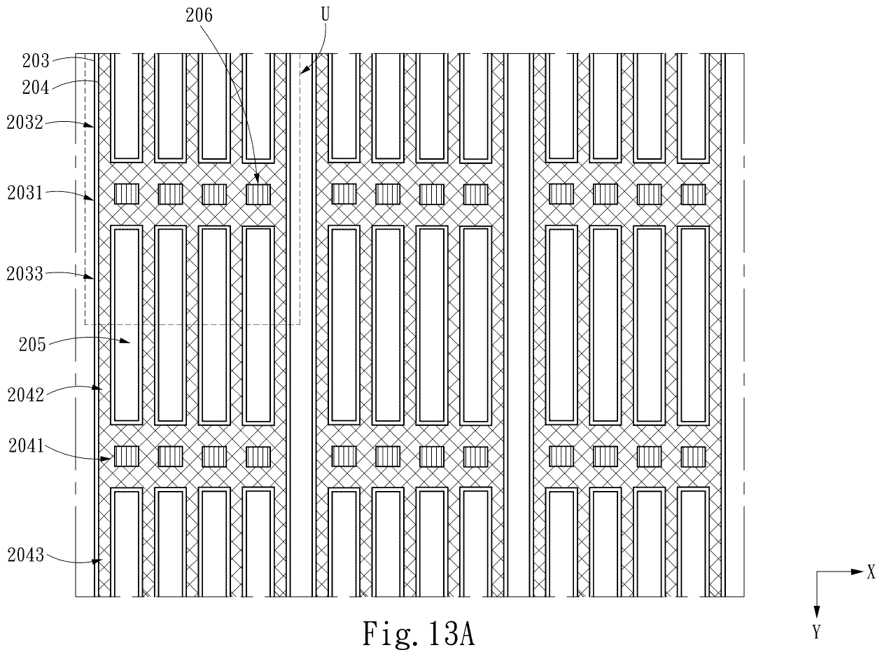

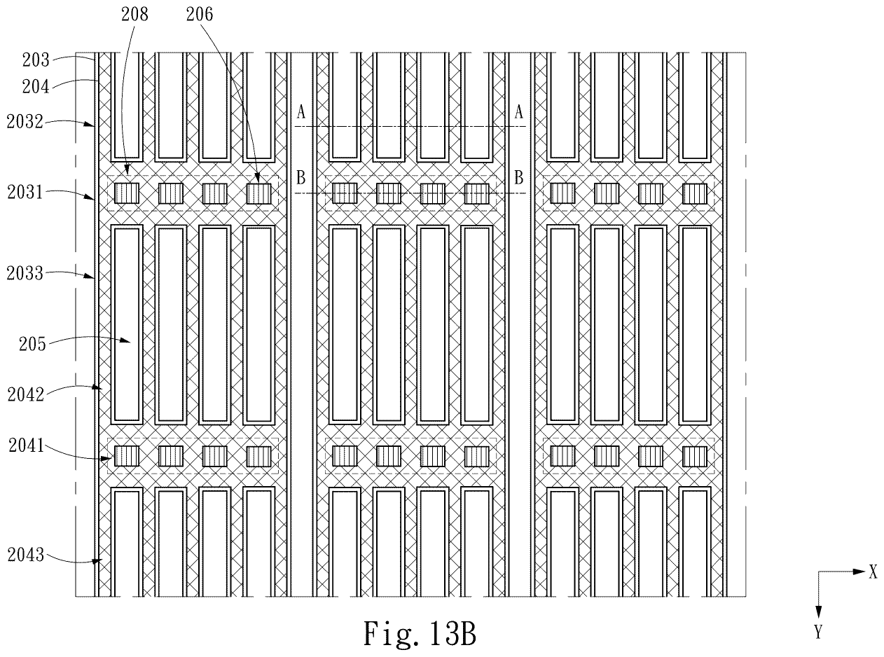

In one example, a distance between the first doped regions 203 and the fifth doped region 207 is 100 nm. And in another example, the distance between the first doped regions 203 and the fifth doped region 207 is 1000 nm. A doping concentration of the third doped region 205 is figured to be high enough, for example, 1E18 cm⁻³, to reduce the resistance induced by the JFET effect between the first doped regions 203 and the fifth doped region 207. The fifth doped region 207 is formed starting from a first depth to a second depth in the normal direction Z. The fourth doped regions 206 are configured to extend deep enough to connect with the fifth doped region 207. The electrically connection between the fourth doped regions 206 and the fifth doped region 207 ensures the first doped regions 203, the second doped regions 204, the fourth doped regions 206 and the fifth doped region 207 can maintain a same electrical potential with the source electrode forming an electric Ohmic contact with a portion of the second doped regions 204 and the fourth doped regions 206 through a plurality of source contact openings 208 landed on the second extending portions 2041. In FIG. 13B, the regions where the source contact openings 208 are located are indicated by dashed lines. The fifth doped region 207 arranged below the JFET regions and electrically connected to the source electrode reduces the gate-to-drain capacitance (Cgd) and increase the gate-to-source capacitance (Cgs).

In these embodiments, a ratio of the gate-to-source capacitance to the gate-to-drain capacitance (Cgs/Cgd) of the device is larger than 200 for a thickness of the drift layer 202 is greater than 5 μm.

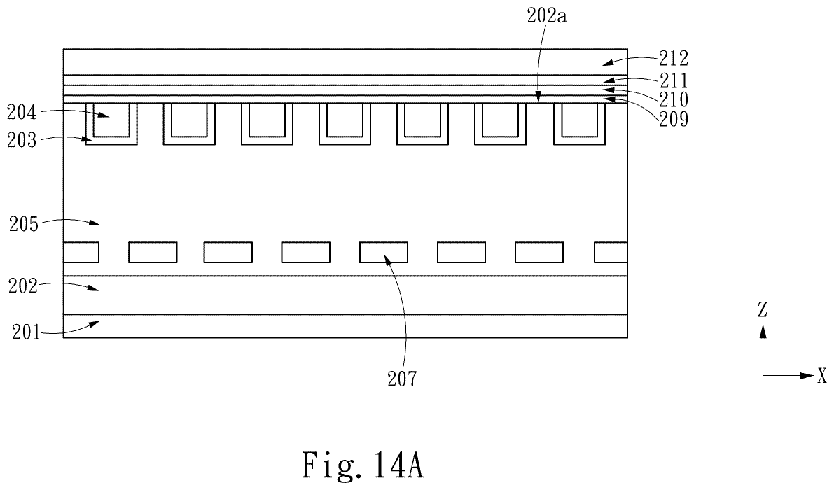

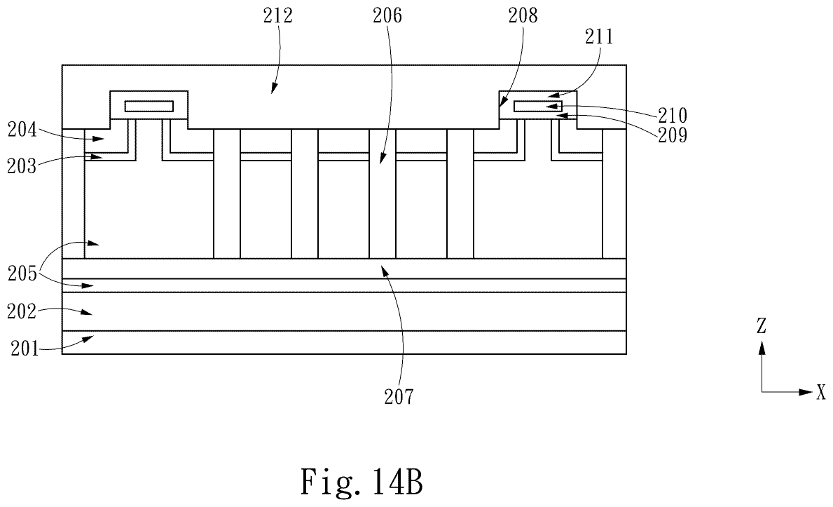

FIG. 14A and FIG. 14B illustrate cross-sectional views taken along lines A-A and B-B in FIG. 13B, respectively. The structures shown in FIG. 14A and FIG. 14B depict an exemplary configuration of the gate and source electrodes in the planar SiC MOSFET. As seen in FIG. 14A, a gate insulating layer 209 is formed on the front surface 202a and a gate electrode 210 is formed on the gate insulating layer 209. Subsequently, an interlayer dielectric (ILD) layer 211 is formed on the gate electrode 210. Referring next to FIG. 13B and FIG. 14B, portions of the gate insulating layer 209, the gate electrode 210 and the ILD layer 211 are removed to form the source contact openings 208 passing through the gate insulating layer 209, the gate electrode 210 and the ILD layer 211. The source contact openings 208 expose the fourth doped regions 206 and a portion of the second doped regions 204. A source electrode 212 is formed over the ILD layer 211 and filled into the source contact openings 208 to electrically contact the fourth doped regions 206 exposed therein. Accordingly, the fifth doped region 207 is electrically connected to the source electrode 212 via the fourth doped regions 206. The ILD layer 211 electrically isolates the source electrode 212 from the gate electrode 210.

What is claimed is:

1. A silicon carbide semiconductor device, comprising:
a drift layer, disposed on a SiC substrate, the drift layer having a first conductivity type and a first doping concentration;
a first doped region having a second conductivity type, formed in the drift layer;
a second doped region having the first conductivity type, formed in the first doped region;
a third doped region having the first conductivity type and a second doping concentration, formed in the drift layer, the second doping concentration is higher than the first doping concentration;
a gate trench extending from an upper surface of the second doped region through the first doped region and into the drift layer, wherein the gate trench is formed in a manner dividing the drift layer into a plurality of mesas encircled by the gate trench, and wherein each of the mesas comprises an extending portion and a plurality of finger portions extended from the extending portion;
a plurality of fourth doped regions having the second conductivity type, formed in the drift layer, wherein each of the fourth doped regions is arranged wholly or partially in the mesas and connected to the first doped region, and wherein each of the fourth doped regions is deeper than the gate trench;
a fifth doped region having the second conductivity type, formed in the drift layer and being below or beneath the gate trench, wherein the fifth doped region is connected to the first doped region through the fourth doped regions to maintain at a same electrical potential;
a gate electrode arranged in the gate trench and dielectrically insulated from the drift layer by a gate insulator; and
a source electrode electrically connected to the second doped region and the fourth doped region through a plurality of contact openings arranged on the extending portion of the plurality of mesas and is dielectrically insulated from the gate electrode.

2. The silicon carbide semiconductor device of claim 1, wherein the plurality of fourth doped regions are arranged wholly in the extending portions of the mesas and the fifth doped region is formed below the gate trench, wherein a distance between a bottom of the gate trench and a top of the fifth doped region is larger than 100 nm.

3. The silicon carbide semiconductor device according to claim 2, wherein the fifth doped region is arranged as rectangular grid below the bottom of the whole gate trench.

4. The silicon carbide semiconductor device according to claim 1, wherein the plurality of mesas comprising at least two finger portions extended from each of two opposite sides of the extending portion, wherein all of the finger portions extend along a lateral direction.

5. The silicon carbide semiconductor device according to claim 1, wherein the plurality of mesas comprising at least four finger portions extended from all four lateral sides of the extending portion.

6. The silicon carbide semiconductor device according to claim 1, wherein the silicon carbide semiconductor device further comprises an edge termination structure, wherein the edge termination structure comprises a plurality of floating guard rings (FGRs), a single-zone or multi-zones junction termination extensions (JTEs) or a combination of FGRs and JTEs, and wherein the FGRs and JTEs are formed by the first doped region, the fourth doped regions and the fifth doped region.

7. The silicon carbide semiconductor device according to claim 1, wherein a depth of the fourth doped regions is at least 50% of a thickness of the drift layer, wherein the fourth doped regions and the fifth doped region form a structure with the drift layer and the third doped region having a charge imbalance between −20% and +20%.

8. A silicon carbide semiconductor device, comprising:
a drift layer, disposed on a SiC substrate, the drift layer having a first conductivity type and a first doping concentration;
a plurality of first doped regions having a second conductivity type, formed in the drift layer, wherein each of the first doped regions comprises an extending portion and a plurality of finger portions;
a plurality of second doped regions having the first conductivity type, formed in the first doped regions;
a third doped region having the first conductivity type and a second doping concentration, formed in the drift layer, the second doping concentration is higher than the first doping concentration, wherein the third doped region has a depth deeper than the first doped regions and forms a JFET region with the first doped regions;
a plurality of fourth doped regions having the second conductivity type, formed in the drift layer, wherein each of the fourth doped regions is arranged in the extending portion of the first doped regions and has a depth deeper than the first doped regions;
a fifth doped region having the second conductivity type, formed in the drift layer, wherein the fifth doped region is arranged partially or wholly below the JFET region and connected to the first doped regions through the fourth doped regions to maintain at a same electrical potential;
a gate electrode provided above the drift layer and dielectrically insulated from the drift layer by a gate insulator; and
a source electrode electrically connected to the second doped regions and the fourth doped regions through a plurality of contact openings arranged on the extending portion of the plurality of first doped regions and is dielectrically insulated from the gate electrode.

9. The silicon carbide semiconductor device of claim 8, wherein a distance between the first doped regions and the fifth doped region is larger than 100 nm.

10. The silicon carbide semiconductor device of claim 8, wherein each of the first doped regions comprises at least two finger portions extended from each of two opposite sides of the extending portion.

11. The silicon carbide semiconductor device of claim 8, wherein the device further comprises a drain electrode provided on a bottom of the SiC substrate, wherein a ratio of a gate-to-source capacitance (Cgs) to a gate-to-drain capacitance (Cgd) is larger than 200 for a thickness of drift layer greater than 5 micron-meter.
